(19) United States
(12) Patent Application Publication
(10) Pub. No.: US 2025/0107197 A1
(43) Pub. Date: Mar. 27, 2025

(54) SPACER TO AVOID SOURCE AND DRAIN SHORTING

(71) Applicant: International Business Machines Corporation, Armonk, NY (US)

(72) Inventors: Ruilong Xie, Niskayuna, NY (US); Shahrukh Khan, Sandy Hook, CT (US); Biswanath Senapati, Mechanicville, NY (US); Julien Frougier, Albany, NY (US); Min Gyu Sung, Latham, NY (US)

(21) Appl. No.: 18/471,645

(22) Filed: Sep. 21, 2023

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/021; H10D 84/0128; H10D 84/013; H10D 84/038; H10D 84/83

(57) ABSTRACT

A semiconductor device that includes a stack of nanostructure material layers overlying a substrate, wherein a gate all around structure is present on a channel region portion for the stack of nanostructure material layers. A bottom source and drain region is present on a first side of the channel region portion, wherein the bottoms source and drain region is composed by a first epitaxial semiconductor material that has a confinement sidewall spacer in direct contact with sidewalls of the first epitaxial semiconductor material defining a lateral dimension for the epitaxial semiconductor material. An upper source and drain region is present on a second side of the channel region portion for the stack of nanostructure material layers. The upper source and drain region is composed of a second epitaxial semiconductor material that partially extends over the confinement sidewall spacer.

### BACKGROUND

The present disclosure relates to semiconductor devices, and more particularly to semiconductor devices including channel regions integrated within nanosheets and epitaxially grown materials.

Modern integrated circuits are made up of literally millions of active devices such as transistors. Field effect transistors are widely used in the electronics industry for switching, amplification, filtering and other tasks related to both analog and digital electrical signals. Most common among these are metal oxide semiconductor field effect transistors, in which a gate structure is energized to create an electric field in an underlying channel region of a semiconductor body, by which electrons are allowed to travel through the channel between a source region and a drain region of the semiconductor body.

Stacked field effect transistor means stacking 1 transistor over the other to increase the transistor density at given footprint. One challenge to forming stacked field effect transistor devices is to form contacts for top or bottom source/drains without shorting to neighboring structures.

### SUMMARY

In one aspect, a semiconductor device is provided that includes a stack of nanostructure material layers, wherein a gate structure is present on a channel region portion for the stack of nanostructure material layers. The semiconductor device may also include first source and drain regions that are present on a first region of the channel region portion. In some embodiments, the first source and drain regions are comprised of a first epitaxial semiconductor material that has a confinement sidewall spacer in direct contact with sidewalls of the first epitaxial semiconductor material defining a lateral dimension for the epitaxial semiconductor material. Second source and drain regions are present on a second region of the channel region portion for the stack of nanostructure material layer. The second source and drain regions are composed of a second epitaxial semiconductor material that partially extends over the confinement sidewall spacer.

In another embodiment, a semiconductor device is provided that includes a stack of nanostructure material layers, wherein a gate structure is present on a channel region portion for the stack of nanostructure material layers. A bottom source and drain region is present on a first side of the channel region portion, wherein the bottoms source and drain region is composed by a first epitaxial semiconductor material that has a confinement sidewall spacer in direct contact with sidewalls of the first epitaxial semiconductor material defining a lateral dimension for the epitaxial semiconductor material. An upper source and drain region is present on a second side of the channel region portion for the stack of nanostructure material layers. The upper source and drain region is composed of a second epitaxial semiconductor material that partially extends over the confinement sidewall spacer. A power contact extends from the upper source and drain region to a backside power rail contact, wherein the power contact is separated from the lower source and drain region by the confinement sidewall spacer.

In another aspect, a method of forming a semiconductor device is provided. In one embodiment, the method includes forming suspended channel regions, the suspended channel regions having an upper portion and a lower portion having a same width. The method may continue with forming lower source and drain regions using a first epitaxial growth process on the lower portion of the suspended channel regions, wherein lateral growth of the epitaxial semiconductor material is confined with a confinement sidewall spacer. In a later process, the method continues with forming an upper source and drain regions using a second epitaxial growth process, wherein the epitaxial semiconductor material for the upper source and drain regions extends over the confinement sidewall spacer.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a side cross-sectional view through a source and drain cross-section along section line Y2-Y2 of a semiconductor device having upper and lower source and drain regions, in which the lower source and drain regions include epitaxial semiconductor material that is confined in a direction that limits its lateral growth by a sidewall confinement spacer.

FIG. 2 is a top down view illustrating the relationship between cross-section lines identified by X-X, Y1-Y1 and Y2-Y2 for each of the side-cross sectional figures provided herein.

FIG. 3 is a side cross-sectional view along section line X1-X1 of the structure depicted in FIG. 1.

FIG. 4 is a side cross-sectional view along section line Y1-Y1 of the structure depicted in FIG. 1.

FIG. 5 is a side cross-sectional view along section line X-X of an initial structure that may be employed in method that can produce the structures depicted in FIGS. 1-4, in accordance with one embodiment of the present disclosure.

FIG. 6 is a side cross-sectional view of the structure depicted in FIG. 5 along section line Y1-Y1.

FIG. 7 is a side cross-sectional view along section line X-X that illustrates one embodiment of forming a replacement gate structure, removal of the second sacrificial nanosheets and the deposition of a dielectric material to provide the dielectric nanosheet geometry spacer.

FIG. 8 is a side cross-sectional view of the structure depicted in FIG. 7 along section line Y1-Y1.

FIG. 9 is a side cross-sectional view of the structure depicted in FIG. 7 along section line Y2-Y2.

FIG. 10 is a side cross-sectional view along section line X-X that illustrates a nanosheet stack recess step that also forms an inner spacer and confinement sidewall spacer, forming a backside contact placeholder, and epitaxial growth of the semiconductor material for the bottom source and drain regions, in accordance with one embodiment of the present disclosure.

FIG. 11 is a side cross-sectional view of the structure depicted in FIG. 10 along section line Y1-Y1.

FIG. 12 is a side cross-sectional view of the structure depicted in FIG. 10 along section line Y2-Y2.

FIG. 13 is a side cross-sectional view along section line X-X that illustrates epitaxial growth of the semiconductor material for the upper source and drain contacts, and substitution of the replacement gate structure with a functional gate structure.

FIG. 14 is a side cross-sectional view of the structure depicted in FIG. 13 along section line Y1-Y1.

FIG. 15 is a side cross-sectional view of the structure depicted in FIG. 13 along section line Y2-Y2.

FIG. 16 is a side cross-sectional view along section line X-X that illustrates one embodiment of cutting a top portion of the functional gate structure followed by filling the opening formed in the top portion of the functional gate structure with a dielectric material.

FIG. 17 is a side cross-sectional view of the structure depicted in FIG. 16 along section line Y1-Y1.

FIG. 18 is a side cross-sectional view of the structure depicted in FIG. 16 along section line Y2-Y2.

FIG. 19 is a side cross-sectional view along section line X-X that illustrates forming middle of the line contacts, back end of the line contacts, and bonding a carrier wafer to the structure depicted in FIG. 16.

FIG. 20 is a side cross-sectional view of the structure depicted in FIG. 19 along section line Y1-Y1.

FIG. 21 is a side cross-sectional view of the structure depicted in FIG. 19 along section line Y2-Y2.

FIG. 22 is a side cross-sectional view along section line X-X that illustrates removal of the supporting structure that includes the substrate.

FIG. 23 is a side cross-sectional view of the structure depicted in FIG. 22 along section line Y1-Y1.

FIG. 24 is a side cross-sectional view of the structure depicted in FIG. 22 along section line Y2-Y2.

### DETAILED DESCRIPTION

Detailed embodiments of the claimed methods, structures and computer products are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

In one embodiment, the disclosed structures and methods can provide a semiconductor device that employs confinement spacers to avoid vias from shorting to bottom source and drain epitaxial semiconductor materials in stacked devices. It has been determined that lateral growth of epitaxial semiconductor material can extend into contact with metal via contacts that are formed for providing electrical contact from upper elements in a stacked semiconductor device, such as upper source and drain epitaxial semiconductor materials, to lower elements in a stacked semiconductor device, such as a power rail, e.g., backside power rail. This is only one example of how the confinement spacers can limit lateral growth of epitaxial semiconductor material to ensure that the material being grown does not result in a short to some electrical current carrying structure. Shorting to via structures can also occur with the upper elements of a stacked semiconductor structure. For example, the epitaxial semiconductor material for upper source and drain regions in a stacked semiconductor device can also experience lateral growth that can result in contacting via contacts. The confinement spacers that are described herein can limit the physical spread of a semiconductor material and can provide for isolation between epitaxial semiconductor material and adjacent electrically conducive features.

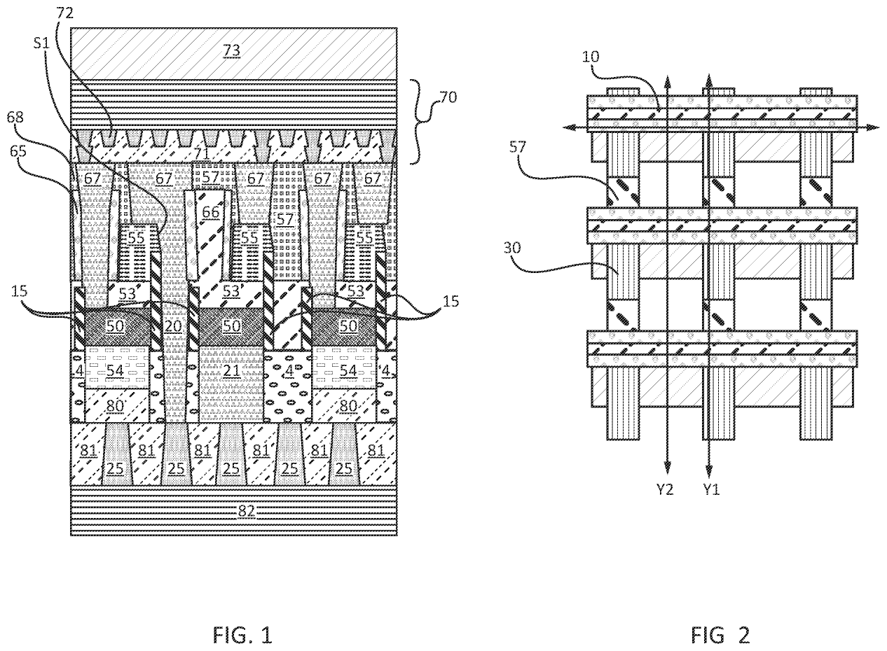

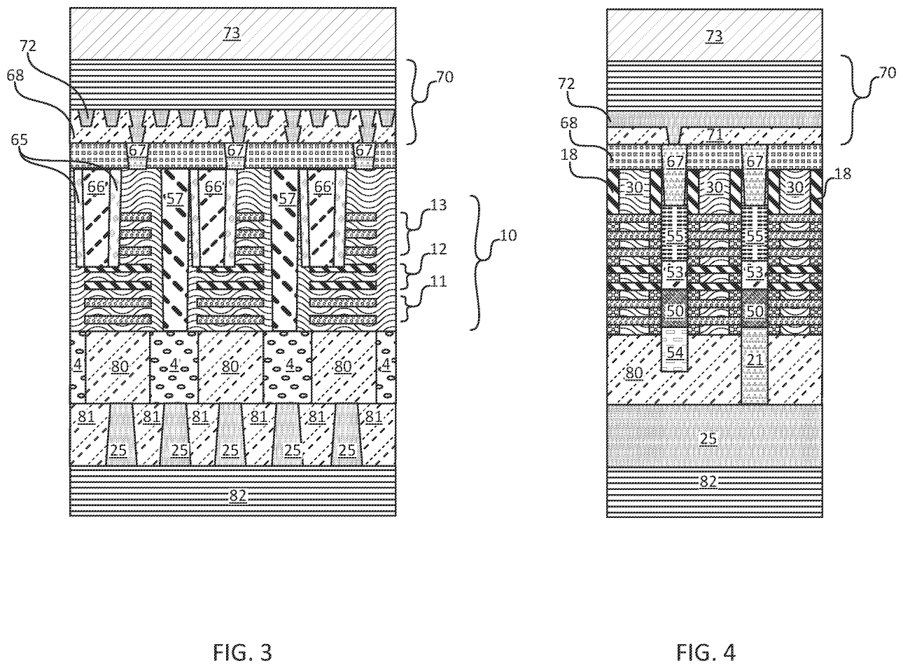

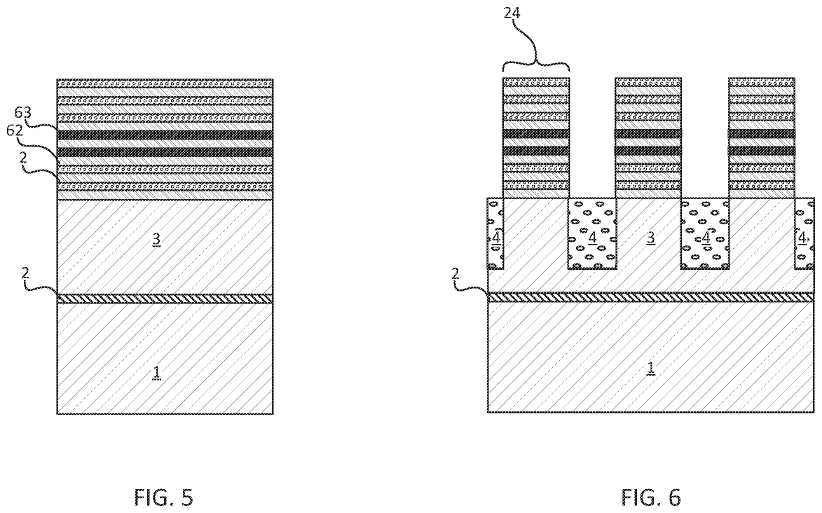

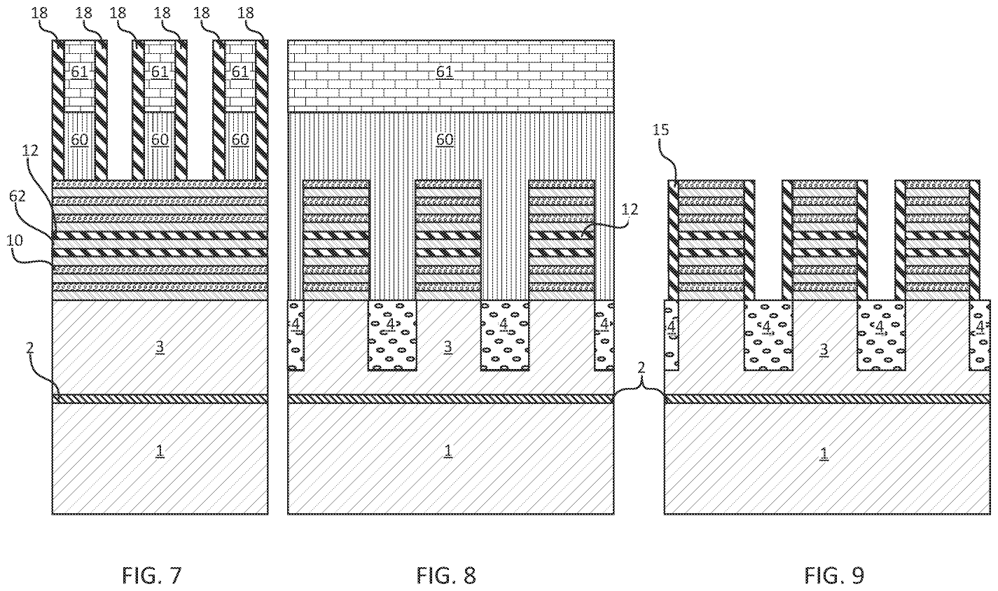

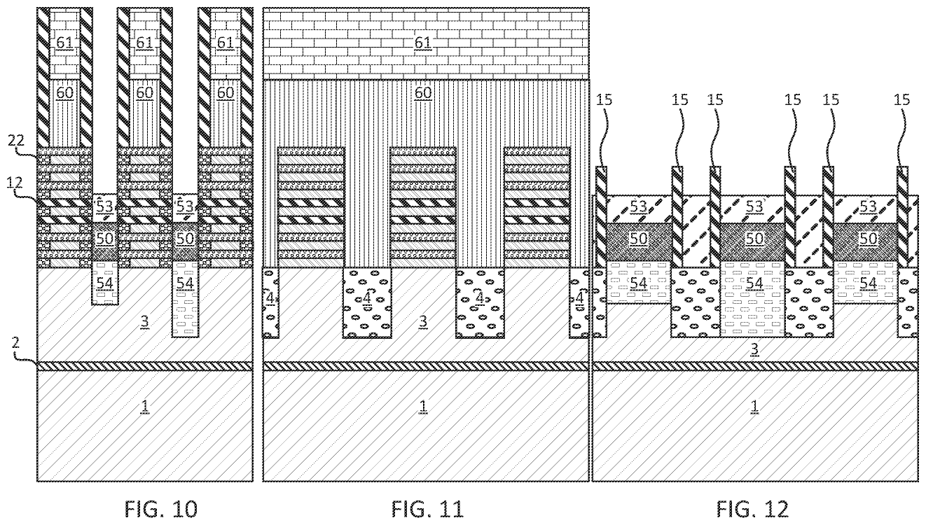

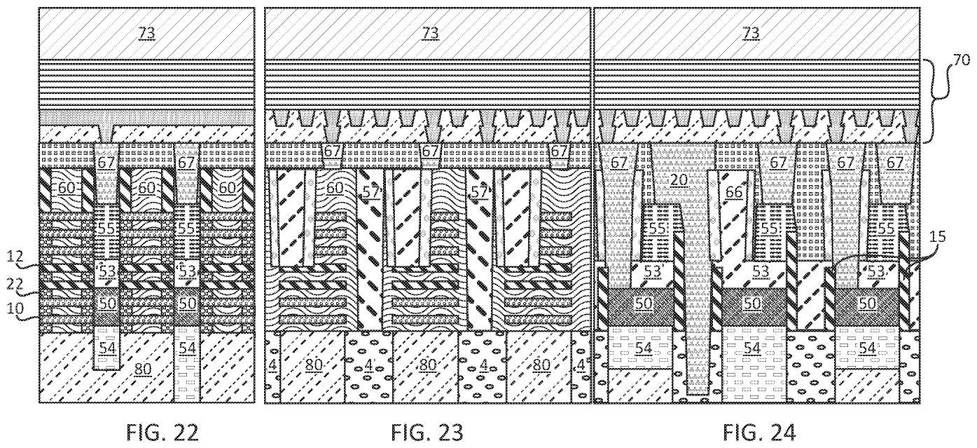

The methods and structures of the present disclosure are now described with reference to FIGS. 1-24.

FIG. 1-4 illustrate one embodiment of a semiconductor device 100 comprising a stack of nanostructure material layers 10, wherein a gate structure is present on a channel region portion for the stack of nanostructure material layers 10. Referring to FIG. 1, the semiconductor device 100 may also include first source and drain regions 50 are present on a first region 11 of the channel region portion of the stack of nanostructure material layers 10. More particularly, the first source and drain regions 50 are formed onto the edges of the first region 11 of the channel region portion of the stack of nanostructure material layers 10. In some embodiments, the first source and drain regions 50 are comprised of a first epitaxial semiconductor material that has a confinement sidewall spacer 15 in direct contact with sidewalls of the first epitaxial semiconductor material defining a lateral dimension for the epitaxial semiconductor material. FIG. 1 further depicts second source and drain regions 55 that are present on a second region 13 of the channel region portion for the stack of nanostructure material layer 10. In some embodiments, the second source and drain regions 55 are composed of a second epitaxial semiconductor material that partially extends over the confinement sidewall spacer 15. It is noted that the first source and drain regions 50 are hereafter referred to as bottom source and drain regions 50, and the first region 11 of the channel region portion of the stack of nanostructure material layers is a bottom region 11 of the nanostructure material layers 10; and the second source and drain regions 55 are upper source and drain regions 55, and the second region 13 of the channel region portion of the stack of nanostructure material layers 10 is an upper region 13 of the nanostructure material layers. It is noted that that the terms “upper” and “lower” are intended to reflect the orientation of the references features as depicted in the supplied figures.

Still referring to FIGS. 1-4 in some embodiments, a power contact 20 extends from the upper source and drain region 55 to a power rail 25. The power rail 25 may be referred to as a back side power rail. As illustrated in FIG. 1, the power contact 20 is separated from the bottom source and drain region 50 by the confinement sidewall spacer 15. More particularly, the confinement sidewall spacer 15 has a first sidewall that is in direct contact with a sidewall of epitaxial semiconductor material for the bottom source and drain region 50, and an opposing second sidewall of the confinement sidewall spacer 15 is in direct contact with the power contact 20, in which the confinement spacer being positioned directly between the source and drain region 50 and the contact 20 electrically isolates the source and drain region 50 from the contact 20. It is noted that the lower epitaxial semiconductor material does not extend above end surfaces of the confinement sidewall spacer 15, and is fully confined by the confinement sidewall spacer 15. This ensures that the lower source and drain 50 is physically separated and therefore electrically isolated from the power contact 20. When referring to “confinement” it is noted that the confinement sidewall spacer 15 provides a barrier against unmitigated lateral growth during the epitaxial growth process that forms the epitaxial semiconductor material for the bottom source and drain region. The bottom source and drain semiconductor contacts 50 are composed of epitaxial semiconductor material.

The term “epitaxial material” denotes a material that is formed using epitaxial growth. The terms “epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The bottom source and drain 50 are epitaxial formed from and in direct contact with edges of the nanosheets 10 for the channel region portion for the stack of nanostructure material layers for the bottom region 11 of the stack. The epitaxial growth is in both a vertical and lateral direction. As will be described in the method for forming the structures depicted in FIGS. 1-4, the epitaxial growth of the bottom source and drain 50 in the lateral direction is obstructed from further growth by the dielectric material confinement spacers 15. In some embodiments, the lower epitaxial semiconductor material for the bottom source and drain 50 does not extend above end surfaces of the confinement sidewall spacers 15, and is fully confined by the confinement sidewall spacer 15.

As noted, the power contact 20 extends from the upper source and drain region 55 to a power rail 25, i.e., back side power rail. In this example, the power contact 20 extends from an upper region of the device to the backside of the device past the bottom source and drain region 50. The power contact 20 is in direct contact with the upper source and drain region 55 but is electrically isolated from the bottom source and drain region 50. More particularly, in some embodiments, the second epitaxial semiconductor material for the upper source and drain region 55 extends above at least one end surface of the confinement sidewall spacer 15. This provides an exposed portion of sidewall material of epitaxial semiconductor material provide a partially exposed sidewall S1 for the second epitaxial semiconductor material. The power contact 20 is in direct contact with the partially exposed sidewall S1 and provides a continuous electrically conductive element from the upper source and drain region 55 to the backside power rail 25, as depicted in FIG. 1.

Referring to FIGS. 1-4, the lower source and drain regions 50 may also be connected to the power rail 25 by a backside contact 21. It is further noted that the upper source and drain regions 55 and the lower source and drain regions 50 are separated by a dielectric spacer 53 that is positioned therebetween. In some embodiments, a dielectric nanosheet geometry spacer 12 is also present between the upper region 13 and lower region 11 of the stack of nanostructure material 10

In some embodiments, the bottom source and drain regions 50 and the gate structure 30 are configured to provide a gate all around (GAA) nanosheet device. A nanosheet device is a field effect transistor that positions the channel is a semiconductor material having the geometry of a nanosheet. As used herein a “field effect transistor” is a transistor in which output current, i.e., source-drain current, is controlled by the voltage applied to the gate. A field effect transistor has three terminals, i.e., gate, source and drain. A “gate structure” means a structure used to control output current (i.e., flow of carriers in the channel) of a semiconducting device, such as a field effect transistor (FET). As used herein, the term “channel” is the region underlying the gate structure and between the source and drain of a semiconductor device that becomes conductive when the semiconductor device is turned on. As used herein, the term “drain” means a doped region in semiconductor device located at the end of the channel, in which carriers are flowing out of the transistor through the drain. As used herein, the term “source” is a doped region in the semiconductor device, in which majority carriers are flowing into the channel. A “nanosheet” is a two-dimensional nanostructure with thickness in a scale ranging from 1 nm to 100 nm. In other embodiments, the nanostructure material layers 10 may be a nanowire. A “nanowire” is similar to a nanosheet, yet has a substantially circular or oblong cross-section. In one example, the nanosheets and/or nanowires may be composed of a type IV semiconductor, such as silicon (Si), germanium (Ge) and/or silicon germanium (SiGe). The nanosheets and/or nanowires may also be provided by a type III-V semiconductor material, such as gallium arsenide (GaAs).

The term gate all around denotes that the gate structure that encloses the channel region from both a frontside and backside of the channel. In some embodiments, a conformal dielectric layer is formed on suspended channels of a multiple channel region device, such as a vertically stacked nanosheet or nanowire structure. Thereafter, a gate conductive is formed, in which a single gate structure may enclose a plurality of channel regions having the conformal gate dielectric present thereon. In some instances, the gate all around structure may include a conformal gate dielectric layer (not shown) composed of a high-k gate dielectric material, and a gate conductor of an elemental metal (which may be referred to as a metal gate).

In some embodiments, the second source and drain regions 55 and the gate structure 30 are configured to provide a forksheet device. In “forksheet” field effect transistors, different than gate all around field effect transistors where gate wraps around the entire channel sheet, forksheet field effect transistor has nanosheets attaching to a dielectric bar and gate only wraps around those surfaces do not attach to the dielectric bar.

The structures illustrated in FIGS. 1-4 are now described in greater detail in accordance with the following embodiments of a method for forming a semiconductor device. It is noted that the following methods are only some examples of methods for forming the structures depicted in FIGS. 5-24.

FIGS. 5 and 6 illustrate one embodiment of an initial structure that may be employed in method employing confined spacer formation to avoid shorting of vias to the epitaxial material of the bottom source and drain regions. The structures depicted in FIGS. 5 and 6 includes a nanosheet fin stack 24 (e.g., including nanosheets), a shallow trench isolation region 4 on a support structure including an upper semiconductor layer 3, an etch stop layer 2 and a supporting substrate 1.

The upper semiconductor layer 3, etch stop layer 2 and supporting substrate 1 may each be composed of semiconductor materials that are selected to provide for etch selectivity in accordance with the process flow described herein.

The stack of nanosheets 10, 62, 63 that is patterned to provide the fin stack 24 may also be provided by a type IV semiconductor material, such as silicon, silicon germanium, etc., or a type III-V semiconductor material, such as gallium arsenide (GaAs). It is noted that any semiconductor material that may serve as the channel region of a field effect transistor may be employed for the nanosheets 10. It is noted that the stack of nanosheets may include a first sacrificial nanosheet 62 that is present on the upper semiconductor layer 3 of the supporting structure 10. Nanosheets 10 ultimately provide the channel regions of the semiconductor devices and are also present in the stack. A second sacrificial nanosheet 63 is also present in the stack.

Each of the layers in the nanosheets stack may be composed of a type IV semiconductor composition. For example, the nanosheet stack may be a multilayered structure composed of silicon nanosheets 10 which are ultimately processed to provide channel regions of the semiconductor device, while the first sacrificial nanosheets 62 that are removed to provide suspended channels are composed of silicon germanium (SiGe30) layer having 30% germanium (Ge) content.

The second sacrificial nanosheets 63 may be removed and replaced with a dielectric material to provide the dielectric nanosheet geometry spacer 12 may be composed of a silicon germanium layer (SiGe55) having 55 wt. % germanium.

The stack of the layered semiconductor materials for the nanosheets may be formed using a deposition process, such as epitaxial deposition. The thickness of each layer within the stack of the layered nanosheets may range from 1 nm to 30 nm. In another embodiment, the thickness of each layer within the stack of nanosheets may range from 5 nm to 20 nm.

In some embodiments, the stack of the layered nanosheets is patterned and etched to provide fin structures 64 for transistor devices. To pattern the structure, a mask layer (not shown) may be formed atop the stack of nanosheets. The pattern process sequence may be used in combination with process steps for forming isolation regions 4. In some examples, a hardmask may be used for patterning the stack of nanosheets. In some embodiments, the hardmask may be composed of a nitride, such as silicon nitride.

For example, a pattern (not shown) is produced by applying a photoresist to the surface to be etched; exposing the photoresist to a pattern of radiation; and then developing the pattern into the photoresist utilizing conventional resist developer. Once the patterning of the photoresist is completed, the sections of the nanosheet stack covered by the photoresist are protected while the exposed regions are removed using a selective etching process that removes the unprotected regions. The etch process may include a direction etch process, such as reactive ion etching.

FIGS. 7-9 illustrate one embodiment of forming a replacement gate structure 60, removal of the second sacrificial nanosheets and the deposition of a dielectric material to provide the dielectric nanosheet geometry spacer. By “replacement”, e.g., as used to describe the replacement gate structure 60, it is meant that the structure is present during processing of the semiconductor device, but is removed from the semiconductor device prior to the device being completed. As used herein, the term “replacement gate structure” denotes a sacrificial structure that dictates the geometry and location of the later formed functioning gate structure. The “functional gate structure” operates to switch the semiconductor device from an “on” to “off” state, and vice versa.

In one embodiment, the sacrificial material that provides the replacement gate structure 60 may be composed of any material that can be etched selectively to the at least one of the stack of nanosheets. In one embodiment, the sacrificial material of the replacement gate structure 60 may be composed of a silicon-including material, such as polysilicon. In another embodiment, the sacrificial material of the replacement gate structure may be composed of a dielectric material, such as an oxide or amorphous carbon. The replacement gate structure 60 may be formed using deposition (e.g., chemical vapor deposition) photolithography and etch processes (e.g., reactive ion etching). In some embodiments, a mask structure may be employed as illustrated by reference number 61. The mask structure 61 may be provided using deposition and photolithography steps, and may be employed in combinations with the directional, i.e., anisotropic, etch processes to shape the geometry of the replacement gate structure 61 that is composed of the sacrificial material. Using the mask structure 61, the sacrificial material that provides the replacement gate structure 60 may be etched to provide the gate geometry in accordance with the mask 61 using a directional etch process, such as reactive ion etching.

FIGS. 7-9 also illustrate one embodiment of removing the second sacrificial nanosheet 63 and replacing it with a dielectric material to provide the dielectric nanosheet geometry spacer 12. The second sacrificial nanosheets 63 is in the same patterned stack as the nanosheets 10 that provide the channel regions for the transistors. Therefore, by removing the second sacrificial nanosheets 63 and forming the dielectric material within the space provided by removing the second sacrificial nanosheets 63 to provide the dielectric nanosheet geometry spacer 12; the dielectric nanosheet geometry spacer 12 has a geometry similar to the nanosheets 10.

In one embodiment, the second sacrificial nanosheets 63 is a silicon germanium having a high germanium content, e.g., 55% germanium within the silicon germanium material. In one embodiment, the second sacrificial nanosheets 63 may be removed by an isotropic etch, e.g., non-directional etch, such as a gas etch, or plasma etch. In some embodiments, the etch process for removing the second sacrificial nanosheets 63 is selective to the other material layers identified by reference numbers 10 and 62 in the stacks that are processed to provide the nanosheets 10 for the channel regions of the semiconductor devices. As used herein, the term “selective” in reference to a material removal process denotes that the rate of material removal for a first material is greater than the rate of removal for at least another material of the structure to which the material removal process is being applied. For example, in one embodiment, a selective etch may include an etch chemistry that removes a first material selectively to a second material by a ratio of 10:1 or greater, e.g., 1000:1. For example, the etch process may remove the silicon and germanium (SiGe) containing material having a germanium content of 55 wt. % of the second sacrificial nanosheet 63 without removing the semiconductor material of silicon (Si) that provides the nanosheets 10 for the channel region, and/or without removing the layers 62 composed silicon and germanium (SiGe) having a germanium (Ge) content of 30%.

FIGS. 7-9 further illustrate one embodiment of filling the space that is formed by removing the first sacrificial nanosheet 63 with a dielectric material to provide the dielectric nanosheet geometry spacer 12 that is positioned between the nanosheets for the lower region 11 of the stack 10 and the upper region 13 of the stack. Forming the dielectric nanosheet geometry spacer 12, may include a process sequence that also forms a gate spacer 18.

The space provided by removing the first sacrificial nanosheet 62 is filled with a dielectric material using deposition and etch back processes to provide the electrically insulating substrate isolation layer 25. For example, the dielectric nanosheet geometry spacer 12 may be composed of a dielectric material, such as silicon nitride or silicon oxide, and may be formed using a deposition process, such as chemical vapor deposition or atomic layer deposition. In some embodiments, following deposition of the material for the dielectric nanosheet geometry spacer 12, an etch back process, such as reactive ion etching may be employed to further tailor the geometry of the layer. The etch back process may include a direction etch, such as reactive ion etching. The gate spacer 18 that is abutting the replacement gate structure 60 may also be formed using deposition and etch back processes, as described for forming the dielectric nanosheet geometry spacer 12. During the formation of the dielectric spacer dielectric nanosheet geometry spacer 12, the material for the confinement sidewall spacer 15 is also formed, as depicted in FIG. 9.

FIGS. 10-12 illustrate a nanosheet stack recess step. FIGS. 1-12 also illustrate forming an inner spacer 22 for supporting the nanosheets 10 during process, as well as forming the confinement sidewall spacer 15. FIGS. 10-12 also illustrate forming a backside contact placeholder 54, epitaxial growth of the semiconductor material for the bottom source and drain regions 50, as well as forming the dielectric material for a lower interlevel dielectric layer, which provides the dielectric spacer 53 between the upper source and drain regions 55 and the lower source and drain regions 50.

FIGS. 10-12 illustrate one embodiment of an anisotropic fin recess. Following the anisotropic etching to recess the fin stack, an isotropic etch, such as a plasma etch, may be performed to indent the sacrificial SiGe sheets 62.

The inner spacer 22 may be formed by indenting the ends of the first sacrificial nanosheets 62 relative to the nanosheets identified by reference number 10 in the patterned stacks. For example, the first nanosheets 62 may be composed of silicon germanium (SiGe30) layer having 30% germanium (Ge) content, i.e., low germanium (Ge) content silicon germanium (SiGe). Indentation may include an etch process that isotropically removes the low germanium (Ge) content silicon germanium (SiGe) relative to the silicon (Si) material of the nanosheets 10.

In a following step, the dielectric material for the inner spacer 22 may be conformally deposited using a chemical vapor deposition process process, such as plasma enhanced chemical vapor deposition or metal organic chemical vapor deposition. In yet further embodiments, the dielectric material for the inner spacer 22 may be atomic layer deposition. The inner spacer 22 may be composed of a nitride or oxide material. For example, the inner spacer 22 may be composed of a nitride, such as silicon nitride, or the outer spacer may be composed of an oxide, such as silicon oxide. An etch back process may remove the portion of the dielectric layer extending outside of the recesses formed by indenting the first sacrificial nanosheets 62, in which the remaining portions of the dielectric filling the recesses provides the inner spacers 22.

FIGS. 10-12 also illustrate forming a backside contact placeholder 54. The backside contact placeholder 54 can be considered as a deep placeholder that can be substituted with a backside contact after forming the bottom source and drain regions 50, and following backside processing that removes the supporting structure including the substrate 1, etch stop layer 2 and upper semiconductor layer 3. The backside contact placeholder 54 is formed by etching a trench in the upper semiconductor layer 3 using an anisotropic etch, such as reactive ion etching, followed by filling the trench with a dielectric material, e.g., SiGe, oxide, nitride or oxynitride material, which in some implementations can include carbon. The composition is generally selected for etch selectivity in removal of the backside contact placeholder 54 in the process sequence that forms the backside contact 21.

FIGS. 10-12 further illustrate epitaxial growth of the semiconductor material for the bottom source and drain regions 50. The bottom source and drain 50 may be formed by an epitaxial deposition method. The source and drain regions may be composed of epitaxial semiconductor material that is doped to an n-type or p-type dopant. In some embodiments, the epitaxial semiconductor material that provides the bottom source and drain 50 may be composed of silicon (Si), germanium (Ge), silicon germanium (SiGe), silicon doped with carbon (Si:C), or the epitaxial semiconductor material that provides the source and drain regions may be composed of a type III-V compound semiconductor, such as gallium arsenide (GaAs).

The epitaxial semiconductor material for the bottom source and drain 50 may be in situ doped to a p-type or n-type conductivity. The term “in situ” denotes that a dopant, e.g., n-type or p-type dopant, is introduced to the base semiconductor material, e.g., silicon or silicon germanium, during the formation of the base material. For example, an in situ doped epitaxial semiconductor material may introduce n-type or p-type dopants to the material being formed during the epitaxial deposition process that includes n-type or p-type source gasses. In the embodiments in which the semiconductor device being formed has p-type source and drain regions, and is referred to as a p-type semiconductor device, the doped epitaxial semiconductor material is doped with a p-type dopant to have a p-type conductivity. As used herein, “p-type” refers to the addition of impurities to an intrinsic semiconductor that creates deficiencies of valence electrons. In a type IV semiconductor, such as silicon, examples of p-type dopants, i.e., impurities, include but are not limited to, boron, aluminum, gallium and indium. As used herein, “n-type” refers to the addition of impurities that contributes free electrons to an intrinsic semiconductor. In a type IV semiconductor, such as silicon, examples of n-type dopants, i.e., impurities, include but are not limited to antimony, arsenic and phosphorous.

The epitaxial semiconductor material for the bottom source and drain 50 is grown from the edges of the fin nanosheets 10 in the lower region 11 of the nanosheet stack 10. The lateral growth of the epitaxial semiconductor material for the bottom source and drain 50 is limited by the confinement sidewall spacer 15, as illustrated in FIG. 12. FIG. 12 illustrates full confinement of the epitaxial semiconductor material for the bottom source and drain 50 by the confinement sidewall spacer 15.

FIGS. 10-12 also illustrate forming a dielectric material for a lower interlevel dielectric layer, which provides the dielectric spacer 53 between the upper source and drain regions 55 and the lower source and drain regions 50. The dielectric material for the dielectric spacer 53 may be deposited using a chemical vapor deposition process process, such as plasma enhanced chemical vapor deposition or metal organic chemical vapor deposition. The dielectric material for the dielectric spacer 53 may be composed of a nitride, such as silicon nitride, or the dielectric material for the dielectric spacer 53 may be composed of an oxide, such as silicon oxide. The deposited dielectric material may then be recessed using an etch process.

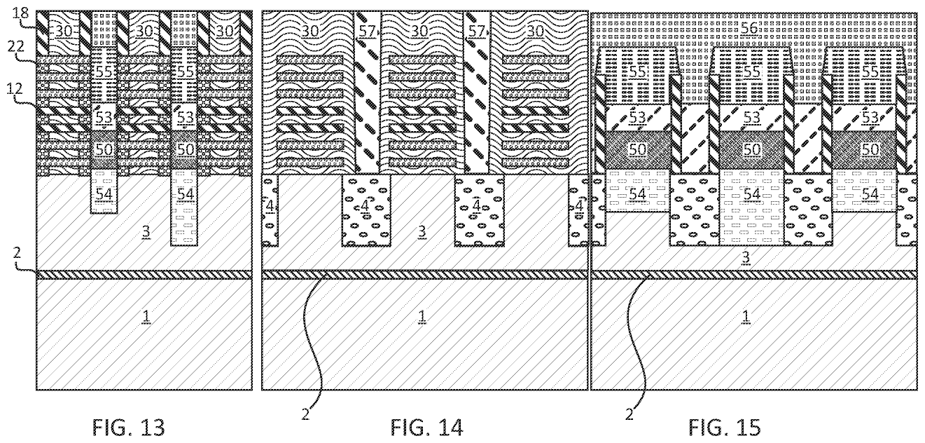

FIGS. 13-15 illustrate epitaxial growth of the semiconductor material for the upper source and drain regions 55 and substitution of the replacement gate structure with a functional gate structure 30.

The upper source and drain regions 55 may be formed by an epitaxial deposition method. The source and drain regions may be composed of epitaxial semiconductor material that is doped to an n-type or p-type dopant. In some embodiments, the epitaxial semiconductor material that provides the upper source and drain regions 55 may be composed of silicon (Si), germanium (Ge), silicon germanium (SiGe), silicon doped with carbon (Si:C), or the epitaxial semiconductor material that provides the source and drain regions may be composed of a type III-V compound semiconductor, such as gallium arsenide (GaAs). The epitaxial semiconductor material for the upper source and drain regions 55 may be in situ doped to a p-type or n-type conductivity.

The epitaxial semiconductor material for the upper source and drain regions 55 is grown from the edges of the fin nanosheets 10 in the upper region 13 of the nanosheet stack 10. The lateral growth of the epitaxial semiconductor material for the upper source and drain regions 55 is not fully confined, and results in some sidewall exposure, as illustrated in FIG. 15. FIG. 15 illustrates partial confinement of the epitaxial semiconductor material for the bottom source and drain regions 55 by the confinement sidewall spacer 15.

Following the growth of the epitaxial semiconductor material for the upper source and drain regions 55, an upper interlevel dielectric layer 56 is deposited and planarized.

The upper interlevel dielectric layer 56 may have a composition selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (also known as amorphous hydrogenated carbon, α-C:H). The interlevel dielectric layer may be deposited using a deposition process, such as spin on deposition followed by a planarization process, such as chemical mechanical planarization.

In a following process sequence, the method can continue with removing the replacement gate structure 60 and forming a functional gate structure 30, which may include a high-k gate dielectric and a metal gate conductor.

In some embodiments prior to the replacement gate sequence, a gate cut 57 may be formed using an anisotropic etch followed with a dielectric deposition to fill the opening provided by the etch process, as illustrated in FIG. 14.

The mask structure 61 and replacement gate structure 60 may then be removed using a selective etch process. More particularly, removing the replacement gate structure 60 using a selective etch process may include removing the sacrificial material for the replacement gate structure 60 and the mask structure identified by reference number 61, without removing the semiconductor material layers in the stack for providing the nanosheets 10. In some embodiments, once the sacrificial gate structure 60 is removed, the remaining portions of the first sacrificial nanosheets 62 are removed by an etch selective to the nanosheets 10 that provide the channel regions for the stacks of nanosheets 10. Suspension of the channel regions for the stacks of nanosheets 10 may be provided by the inner spacers 22. In some embodiments, the suspended semiconductor layers provided by the nanosheets 10 may be further processed to provide reduced dimension nanostructure, e.g., nanowires and/or nanosheets. In some embodiments, the suspended structure, e.g., semiconductor material layer provided by nanosheets 10, may be further processed to a geometry in the nanometer regime. For example, the semiconductor material layers (also referred to as nanosheets 10) may be thinned by a process that includes controlling thinning of the silicon (Si) containing nanosheets 5, which can include ozone (O₃) oxidation, SC1 chemistry oxidation and/or dry oxidation. The geometry may also be modified to provide nanowires.

The method continues with the forming a functional gate structure 30 in the space that was created by removing the replacement gate structure 60. In some embodiments, the functional gate structure 30 includes a high-k gate dielectric and a metal gate conductor. The gate dielectric may be a high-k dielectric material, such as hafnium oxide (HfO₂). The gate dielectric for the gate all around structure may be deposited using chemical vapor deposition or atomic layer deposition and is present on the entirety of the exterior surfaces of the suspended nanosheets 10. The metal gate conductor for the gate structure 30 may encapsulate the suspended nanosheets 10 including the gate dielectric present on the exterior surfaces of the suspended nanosheets 10. The gate conductor may be composed of a metal, such as tungsten (W) or an n-type or p-type work function metal, e.g., titanium nitride. It is noted that the prior examples are provided for illustrative purposes only, and are not intended to limit the teachings of this disclosure solely thereto. For example, the gate conductor for the gate all around structure that provides the functional gate structure 30, e.g., gate all around gate structure, may be composed of other conductive materials, such as a doped semiconductor, e.g., n-type doped polysilicon. Each of the aforementioned layers may be formed using a deposition method, such as chemical vapor deposition, atomic layer deposition, plating, physical vapor deposition, etc.

The gate structure of the present devices identified by reference number 30 may be a gate all around structure. In some embodiments, a conformal dielectric layer is formed on suspended channels of a multiple channel region device, such as a vertically stacked nanosheet or nanowire structure. Thereafter, a gate conductive is formed, in which a single gate structure may enclose a plurality of channel regions having the conformal gate dielectric present thereon. In some instances, the gate all around structure may include a conformal gate dielectric layer composed of a high-k gate dielectric material, and a gate conductor of an elemental metal (which may be referred to as a metal gate). A high-k gate dielectric may have a dielectric constant greater than silicon, and in some embodiments may be hafnium based, e.g., be composed of hafnium oxide.

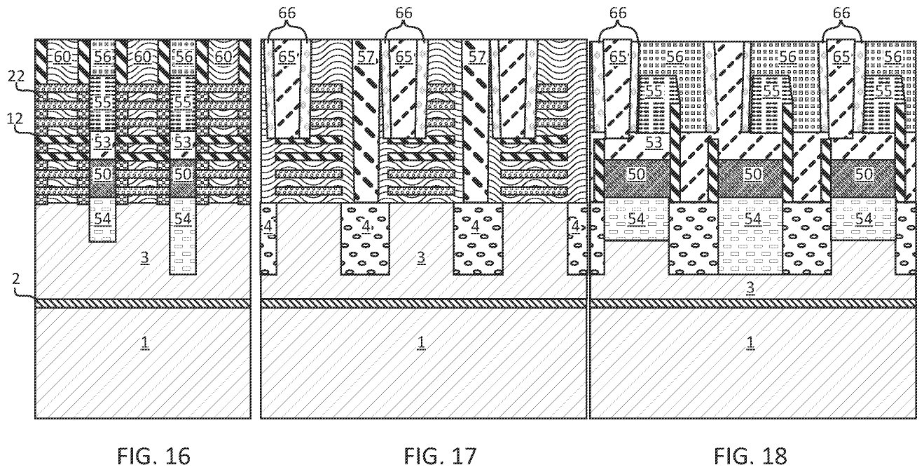

FIG. 16-18 illustrate one embodiment of cutting a top portion of the functional gate structure 30 followed by filling the opening formed in the top portion of the functional gate structure 30 with a dielectric material. In some embodiments, by removing a top portion of the functional gate structure 30 parasitic capacitance can be reduced.

More particularly, an etch process, such as reactive ion etching, can cut the top portion of the functional gate structure 30. Thereafter, a bilayer of a nitride containing liner, e.g., silicon nitride liner 65, and an oxide containing fill 66, e.g., silicon oxide fill, can be deposited using a deposition process, such as chemical vapor deposition to fill the etched openings in the functional gate structure 30. Thereafter, a planarization process, such as chemical mechanical planarization, may be applied to provide the structure depicted in FIGS. 17 and 18.

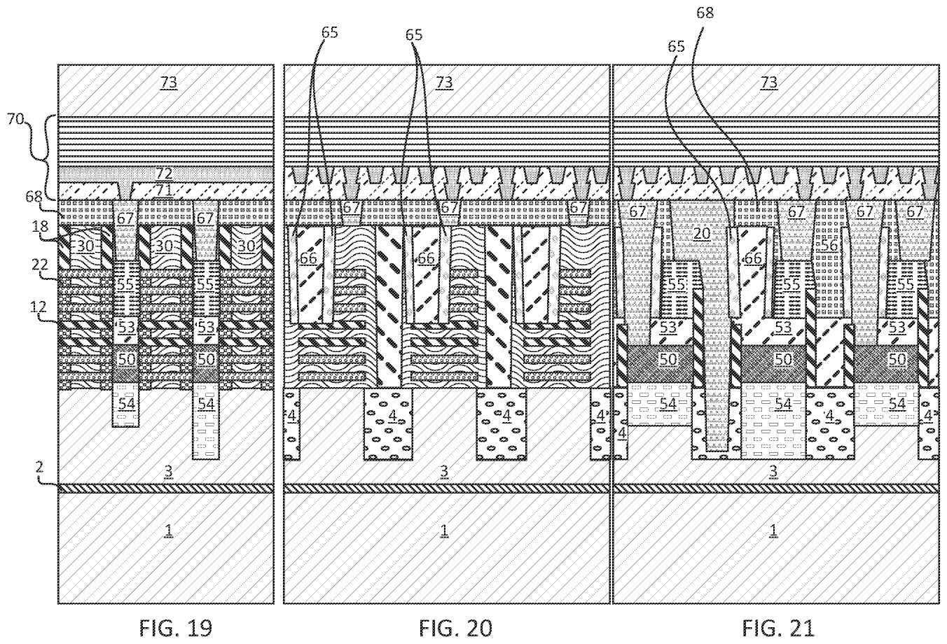

FIGS. 19-21 depict one embodiment of forming middle of the line contacts, back end of the line contacts, and bonding a carrier wafer to the structure depicted in FIGS. 16-18. The middle of the line contacts may include the power contact 20 that in the final device structure extends from the upper source and drain region 55 to a power rail 25. The confinement sidewall spacer 15 ensures that during the formation of the power contact 20, the power contact 20 is not shorted to the bottom source and drain 50. The middle of the line contacts may include the contacts 67 that in the final device structure extends from metallization 72 in the back end of the line layer 70 to the upper and lower source and drain regions 55, 50. Some of these contacts may be formed in via openings that are formed into a dielectric layer 68. For the contact 67 to the bottom source and drain regions 50 that are formed during middle of the line processing, the contact 67 may be formed by removing the oxide containing fill 66 selectively to the nitride liner 65, extending that opening through the dielectric spacer identified by reference number 53 to expose the bottom source and drain region 50, and then filling that opening with a conductive material, as depicted in FIG. 21. This provides that the contact 67 is protected from shorting to the upper source and drain regions 50 by the nitride containing liner 65, as depicted in FIG. 21.

The back end of the line processing level 70 includes metal lines and vias (metallization 72) that may be in electrical communication with the contacts 67 produced in the middle of the line. The process sequence that is used for forming the metal lines and vias is a back end of the line process. In some embodiments, an interlevel dielectric layer 71 is first deposited and then etched to form via openings to the underlying contacts 67. Thereafter, the via openings are then filled with an electrically conductive material, such as a metal, e.g., copper, to provide vias. Thereafter, a deposition, pattern and fill sequence is repeated to forms lines. This may be referred to a single damascene method for forming lines and vias. However, dual damascene sequences are also applicable. The sequence of deposition, pattern and etch are repeated as many times as needed to form each level of metal lines and vias. The metal lines and vias in the back end of the line BEOL processing level 70 may be collectively referred to as metallization 71. The carrier wafer 73 provides support to the structure, as the backside of the device is processed.

FIGS. 22-24 illustrate some embodiments of removal of the supporting structure that includes the substrate 1. In one embodiment, the substrate 1, etch stop layer 2 and remaining portions of the upper semiconductor layer 3 that is present atop the etch stop layer 2 are removed. These elements may be removed by selective etching. For example, the remaining portions of the upper semiconductor layer 3 may then be removed by an etch process that is selective to the isolation regions 4. Thereafter, a backside interlevel dielectric layer 80 may be deposited following a planarization process. The backside interlevel dielectric layer 80 is similar to the upper interlevel dielectric layer 56. Therefore, the above description of the upper interlevel dielectric layer 56 described above is suitable for at least one embodiment of the backside interlevel dielectric layer 80 that is depicted in FIGS. 22-24. The planarization process, which may be provided by chemical mechanical planarization, exposes the backside surface of the backside contact placeholder 54.

Referring back to FIGS. 1-4, in a following process sequence, the backside contact placeholder 54 is removed using an etch process, that may be selective to the bottom source and drain regions 50. Thereafter, the backside contact 21 may be formed within the opening created by removing the backside contact placeholder 54. The backside contact 21 may be formed in direct contact with the backside surface of the bottom source and drain regions 50. The backside contacts 21 may be composed of a metal, such as a silicide liner such as Ti, Ni, NiPt, an thin metal adhesion layer, such as TiN, and conductive metals, such as W, Co, Ru, and alloys or combinations thereof. The backside contacts 21 may be deposited using plating and/or physical vapor deposition. Following deposition, a planarization process may be performed, such as chemical mechanical planarization.

FIGS. 1-4 also depict forming the back side power rail 25. In some embodiments, an interlevel dielectric layer 81 is first deposited and then etched to form via openings to the backside contacts 25, and the power contact 20. Thereafter, the via openings are then filled with an electrically conductive material, such as a metal, e.g., copper, to provide the backside power rail 25.

Thereafter, a deposition, pattern and fill sequence is repeated to forms lines in back side metallization layer 82. This may be referred to a single damascene method for forming lines and vias. However, dual damascene sequences are also applicable. The sequence of deposition, pattern and etch are repeated as many times as needed to form each level of metal lines and vias.

Having described preferred embodiments of a methods and structures for confined spacer formation to avoid deep via to source/drain epitaxial material shorting are disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device comprising:
a stack of nanostructure material layers, wherein a gate structure is present on a channel region portion for the stack of nanostructure material layers;
first source and drain regions are present on a first region of the channel region portion, wherein the first source and drain regions are comprised of a first epitaxial semiconductor material that has a confinement sidewall spacer in direct contact with sidewalls of the first epitaxial semiconductor material defining a lateral dimension for the epitaxial semiconductor material; and
second source and drain regions are present on a second region of the channel region portion for the stack of nanostructure material layer, wherein the second source and drain regions are composed of a second epitaxial semiconductor material that partially extends over the confinement sidewall spacer.

2. The semiconductor device of claim 1, wherein a power contact extends from the second source and drain regions to a power rail, wherein the power contact is separated from the first source and drain regions by the confinement sidewall spacer.

3. The semiconductor device of claim 1, wherein the first source and drain regions are connected to a power rail by a backside contact.

4. The semiconductor device of claim 1, wherein the second source and drain regions and the gate structure are configured to provide a forksheet device.

5. The semiconductor device of claim 1, wherein a dielectric nanosheet geometry spacer is present between the first and second source and drain regions of the stack of nanostructure material layers.

6. The semiconductor device of claim 1, wherein the first source and drain regions and the gate structure are configured to provide a gate all around nanosheet device.

7. The semiconductor device of claim 1, wherein the first epitaxial semiconductor material does not extend above end surfaces of the confinement sidewall spacer.

8. The semiconductor device of claim 1, wherein the first epitaxial semiconductor material is fully confined by the confinement sidewall spacer.

9. The semiconductor device of claim 1, wherein the second epitaxial semiconductor material extends above at least one end surface of the confinement sidewall spacer to provide a partially exposed sidewall for the second epitaxial semiconductor material.

10. A semiconductor device comprising:
a stack of nanostructure material layers, wherein a gate structure is present on a channel region portion for the stack of nanostructure material layers;
bottom source and drain regions present on a first side of the channel region portion, wherein the bottom source and drain regions are composed by a first epitaxial semiconductor material that has a confinement sidewall spacer in direct contact with sidewalls of the first epitaxial semiconductor material defining a lateral dimension for the epitaxial semiconductor material;
upper source and drain regions present on a second side of the channel region portion for the stack of nanostructure material layers, wherein the upper source and drain regions are composed of a second epitaxial semiconductor material that partially extends over the confinement sidewall spacer; and
a power contact extends from the upper source and drain regions to a backside power rail contact, wherein the power contact is separated from a lower source and drain regions by the confinement sidewall spacer.

11. The semiconductor device of claim 10, wherein the first epitaxial semiconductor material does not extend above end surfaces of the confinement sidewall spacer, and is fully confined by the confinement sidewall spacer.

12. The semiconductor device of claim 10, wherein the second epitaxial semiconductor material extends above at least one end surface of the confinement sidewall spacer to provide a partially exposed sidewall for the second epitaxial semiconductor material.

13. A method of forming a semiconductor device comprising:
forming suspended channel regions;
forming lower source and drain regions using a first epitaxial growth process on a lower portion of the suspended channel regions, wherein lateral growth of epitaxial semiconductor material is confined with a confinement sidewall spacer; and
forming upper source and drain regions using a second epitaxial growth process, wherein the epitaxial semiconductor material for the upper source and drain regions extends over the confinement sidewall spacer.

14. The method of claim 13 further comprising forming a power contact that extends from the upper source and drain regions to a backside power rail contact, wherein the power contact is separated from the lower source and drain regions by the confinement sidewall spacer.

15. The method of claim 13 further comprising forming a backside contact on the lower source and drain regions, and connecting the backside contact to a backside power rail.

16. The method of claim 13 further comprising forming a gate structure, wherein an upper portion of the gate structure is cut and filled with a bilayer of a nitride containing liner and an oxide containing fill, the upper portion of the gate structure being cut and filled with dielectric material to reduce parasitic capacitance.

17. The method of claim 16, further comprising forming contacts to the upper source and drain regions, wherein the contacts are formed by removing a dielectric material of the oxide containing fill selectively to a spacer of the nitride containing liner, wherein a conductive material deposited within an opening to the upper source and drain regions formed by removing the oxide containing fill is prevented from shorting to the upper source and drain regions by the nitride containing liner.

18. The method of claim 16, wherein the lower source and drain regions and the gate structure are configured to provide a forksheet device.

19. The method of claim 16, wherein the lower source and drain regions and the gate structure are configured to provide a gate all around nanosheet device.

20. A semiconductor device comprising:
a stack of nanostructure material layers, wherein a gate structure is present on a channel region portion for the stack of nanostructure material layers;
bottom source and drain regions are present on a bottom region of the channel region portion, wherein the bottom source and drain regions are comprised of a first epitaxial semiconductor material that has a confinement sidewall spacer in direct contact with sidewalls of the first epitaxial semiconductor material defining a lateral dimension for the epitaxial semiconductor material; and
top source and drain regions are present on a top region of the channel region portion for the stack of nanostructure material layer, wherein the top source and drain regions are composed of a second epitaxial semiconductor material that partially extends over the confinement sidewall spacer, wherein the bottom source and drain regions and the gate structure are configured to provide a forksheet device.

21. The semiconductor device of claim 20, wherein a power contact extends from the top source and drain regions to a power rail, wherein the power contact is separated from the bottom source and drain regions by the confinement sidewall spacer.

22. The semiconductor device of claim 20, wherein the bottom source and drain regions are connected to a power rail by a backside contact.

23. The semiconductor device of claim 20, wherein a dielectric nanosheet geometry spacer is present between the bottom region and second regions of the stack of nanostructure material layers.

24. The semiconductor device of claim 20, wherein the first epitaxial semiconductor material does not extend above end surfaces of the confinement sidewall spacer, and is fully confined by the confinement sidewall spacer.

25. The semiconductor device of claim 20, wherein the second epitaxial semiconductor material extends above at least one end surface of the confinement sidewall spacer to provide a partially exposed sidewall for the second epitaxial semiconductor material.
